(19) United States
(12) Patent Application Publication
(10) Pub. No.: US 2013/0158931 A1
(43) Pub. Date: Jun. 20, 2013

(54) VOLTAGE TESTING DEVICE

(71) Applicants: YING-FEI CHEN, Shenzhen City (CN); YUAN-XI CHEN, Shenzhen City (CN); HUI LI, Shenzhen City (CN)

(72) Inventors: YING-FEI CHEN, Shenzhen City (CN); YUAN-XI CHEN, Shenzhen City (CN); HUI LI, Shenzhen City (CN)

(73) Assignees: HON HAI PRECISION INDUSTRY CO., LTD., Tu-Cheng (TW); HON FU JIN PRECISION INDUSTRY (ShenZhen) CO., LTD., Shenzhen City (CN)

(21) Appl. No.: 13/572,683

(22) Filed: Aug. 12, 2012

(30) Foreign Application Priority Data
Dec. 17, 2011 (CN) 201110423713.5

(51) Int. Cl. G01R 31/02; G01R 1/067; G06F 19/00

(52) U.S. Cl. 702/108; 324/537; 324/754.01

(57) ABSTRACT

An exemplary voltage testing device includes a testing circuit and an oscillograph. The testing circuit includes a filtering unit, a rectifier unit, and a voltage dividing unit. The filtering unit receives and filters an alternating current (AC) voltage. The rectifier unit receives the filtered AC voltage and rectifies the filtered AC voltage into a first direct current (DC) voltage. The voltage dividing unit receives the first DC voltage, and dividess the first DC voltage into a second DC voltage equaling an effective value of the AC voltage, thereby the second DC voltage is tested and displayed on the oscillograph.

### BACKGROUND

1. Technical Field

The disclosure generally relates to testing devices, and particularly to a voltage testing device for testing parameters of an alternating current (AC) power supply in a computer system.

2. Description of the Related Art

A power supply unit (PSU) in a computer transforms an AC voltage into different steady direct current (DC) voltages. The AC voltage of the PSU is supplied by an AC power supply. In testing performance of the PSU, the AC voltage output to the PSU should be tested, for example, testing the AC voltage value output by the AC power supply and a power margin of the AC power supply when the PSU is turned on and off.

The AC voltage output by the AC power supply is generally tested by a typical testing device, such as an ATE testing device, which is expensive, and takes up too much space, thereby being inconvenient to reduce cost of the testing.

Therefore, there is room for improvement within the art.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views. Wherever possible, the same reference numbers are used throughout the drawings to refer to the same or like elements of an embodiment.

FIG. 1 is a block diagram of a voltage testing device, according to an exemplary embodiment, and showing the voltage testing device connected to an AC power supply.

FIG. 2 is a partial circuit diagram of the voltage testing device shown in FIG. 1.

FIG. 3 is a schematic view of the voltage testing device shown in FIG. 1.

### DETAILED DESCRIPTION

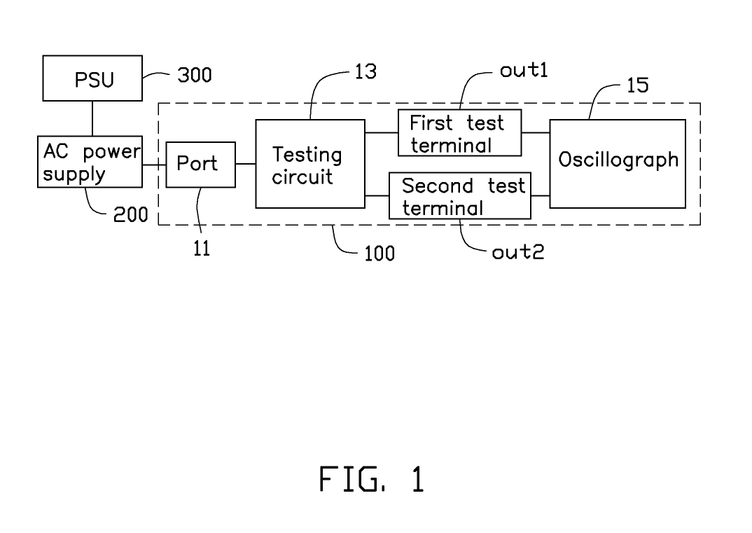

FIG. 1 is a block diagram of a voltage testing device 100, according to an exemplary embodiment. The voltage testing device 100 is connected to an AC power supply 200, and configured for testing an AC voltage output by the AC power supply 200. The AC power supply 200 is also connected to a PSU 300, and supplies the AC voltage to the PSU 300.

The voltage testing device 100 includes a port 11, a testing circuit 13, a first test terminal out1, a second test terminal out2, and an oscillograph 15.

The port 11 can be electronically connected to the AC power supply 200 through a plug. The port 11 receives the AC voltage from the AC power supply 200 through the plug.

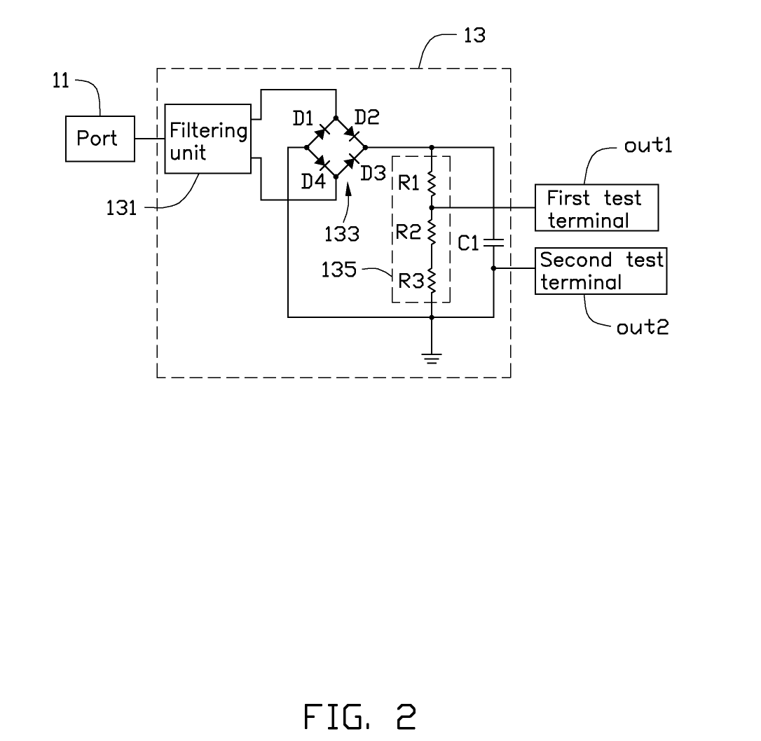

FIG. 2, is the testing circuit 13 of the embodiment. The testing circuit 13 includes a filtering unit 131, a rectifier unit 133, and a voltage dividing unit 135.

The filtering unit 131 can be a typical filter or a filtering circuit having a filtering function. The filtering unit 131 is connected to the port 11, and is thereby connected to the AC power supply 200 through the port 11 to filter the AC voltage from the AC power supply 200.

The rectifier unit 133 is connected to the filtering unit 131, and receives the filtered AC voltage from the filtering unit 131 to rectify the filtered AC voltage into a first DC voltage. In this embodiment, the rectifier unit 133 is a bridge circuit, and includes a first diode D1, a second diode D2, a third diode D3, and a fourth diode D4. A first output of the filtering circuit 131 is connected between the first and second diodes D1, D2. A second output of the filtering circuit 131 is connected between the third and fourth diodes D3, D4. A first terminal of the voltage dividing circuit 135 is connected between the second and third diodes D2, D3, and used for receiving the first DC voltage. A second terminal of the voltage dividing circuit 135 is connected between the first and fourth diodes D1, D4, and is also connected to ground.

The testing circuit 13 further includes a capacitor C1. One terminal of the capacitor C1 is connected between the second and third diodes D2, D3. The other terminal of the capacitor C2 is connected to ground. The capacitor C1 is configured for cooperating with the filtering unit 131, and making the rectifier unit 133 output a pure first DC voltage. In one embodiment, a capacitance of the capacitor C1 is about 1 μF.

The voltage dividing unit 135 receives the first DC voltage output by the rectifier unit 133, and divides the first DC voltage into a second DC voltage. In detail, the voltage dividing unit 135 includes a first resistor R1, a second resistor R2, and a third resistor R3. One terminal of the first resistor R1 is connected between the second and third diodes D2, D3. The other terminal of the first resistor R1 is connected to ground through the second and third resistors R2, R3 which are connected in series.

The first test terminal out1 is connected between the first and second resistors R1, R2. The second test terminal out2 is connected to ground.

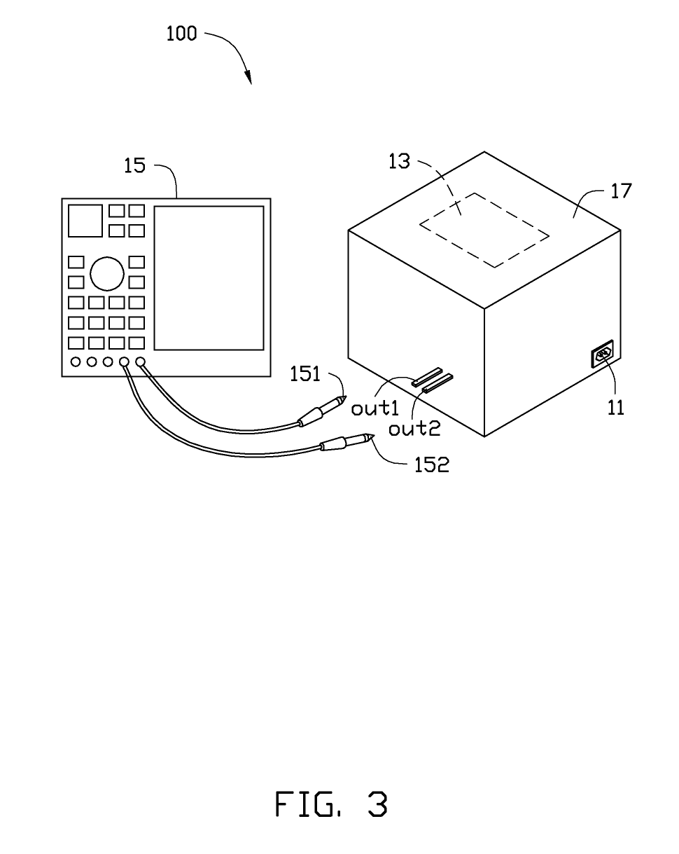

Referring to FIG. 3, the oscillograph 15 includes a testing probe 151 and a grounding probe 152. The testing probe 151 is connected to the first test terminal out1. The grounding probe 152 is connected to the second test terminal out2. Thus, the oscillograph 15 can test and display the second DC voltage value through the connection between the testing probe 151 and the first test terminal out1, and the connection between the grounding probe 152 and the second test terminal out2.

The voltage testing device 100 further includes a housing 17. The port 11, the first test terminal out1, and the second test terminal out2 are all mounted on a surface of the housing 17. The testing circuit 13 is mounted in the inner of the housing 17, thereby preventing injury to an operator due to an exposed AC voltage.

In use, the testing circuit 13 is received in the housing 17, and establishes a connection with the port 11, the first test terminal out1, and the second test terminal out2. Then, the voltage testing device 100 is electronically connected to the AC power supply 200 through the port 11, and the testing probe 151 and the grounding probe 152 of the oscillograph 15 are respectively connected to the first and second test terminals out1, out2. The filtering unit 131 receives and filters an AC voltage from the AC power supply 200, thereby transmitting the filtered AC voltage to the rectifier unit 133. The rectifier unit 133 rectifies the filtered AC voltage into a first DC voltage Vout, and the first DC voltage Vout can be calculated according to the following formula (1):

Vout=\sqrt{2}*Vac (1)

where the parameter Vac is an effective value of the AC voltage.

Then, the voltage dividing unit 135 receives the first DC voltage Vout, and divides the first DC voltage Vout into a second DC voltage Vdc. The second DC voltage Vdc can be calculated according to the following formula (2):

$$Vdc = Vout * \frac{R 2 + R 3}{R 1 + R 2 + R 3} \qquad ( 2 )$$

According to the above formulas (1) and (2), the parameter Vdc can be calculated according to the following formula (3):

$$Vdc = \sqrt{2} * Vac * \frac{R 2 + R 3}{R 1 + R 2 + R 3} \qquad ( 3 )$$

Thus, via selecting corresponding first to third resistors R1-R3, and making the resistances of the first to third resistors R1-R3 satisfy the following formula (4):

$$\sqrt{2} * \frac{R 2 + R 3}{R 1 + R 2 + R 3} = 1 \qquad ( 4 )$$

In this way, the effective value of the AC voltage Vac will equal to the second DC voltage Vdc, thereby the second DC voltage Vdc being displayed on the oscillograph 15 instead of the effective value of the AC voltage Vac.

Accordingly, in use of the voltage testing device 100, the operator only needs to select corresponding first to third resistors R1-R3, and make the resistances of the first to third resistors R1-R3 satisfy a corresponding formula. Then a test of an AC voltage output to the PSU 300 can be effectively transformed into a test of a DC voltage, thereby simplifying a structure of voltage testing device 100, and reducing a cost of the testing.

In the present specification and claims, the word “a” or “an” preceding an element does not exclude the presence of a plurality of such elements. Further, the word “comprising” does not exclude the presence of elements or steps other than those listed.

It is to be also understood that even though numerous characteristics and advantages of exemplary embodiments have been set forth in the foregoing description, together with details of the structures and functions of the embodiments, the disclosure is illustrative only, and changes may be made in detail, especially in matters of arrangement of parts within the principles of this disclosure to the full extent indicated by the broad general meaning of the terms in which the appended claims are expressed.

What is claimed is:

1. A voltage testing device, comprising:
a testing circuit comprising:
a filtering unit that receives and filters an alternating current (AC) voltage;
a rectifier unit connected to the filtering unit, the rectifier unit receiving the filtered AC voltage and rectifying the filtered AC voltage into a first direct current (DC) voltage;
a voltage dividing unit connected to the rectifier unit, the voltage dividing unit receiving the first DC voltage and dividing the first DC voltage into a second DC voltage equaling an effective value of the AC voltage; and
an oscillograph connected to the testing circuit, wherein the oscillograph tests and displays the second DC voltage.

2. The voltage testing device of claim 1, further comprising a port, wherein the port is connected to both an AC power supply and the filtering unit, and wherein the AC voltage is received by the port and output to the filtering unit.

3. The voltage testing device of claim 1, wherein the rectifier unit is a bridge circuit, and comprises a first diode, a second diode, a third diode, and a fourth diode, a first output of the filtering unit is connected between the first and second diodes; a second output of the filtering unit is connected between the third and fourth diodes; a first terminal of the voltage dividing unit is connected to both the second and third diodes; a second terminal of the voltage dividing unit is connected to the first and fourth diodes, and is also connected to ground.

4. The voltage testing device of claim 3, wherein the testing circuit further comprises a capacitor, a first terminal of the capacitor is connected to the second and third diodes, a second terminal of the capacitor is connected to ground.

5. The voltage testing device of claim 4, wherein a capacitance of the capacitor is about 1 μF.

6. The voltage testing device of claim 3, wherein the voltage dividing unit comprises a first resistor R1, a second resistor R2, and a third resistor R3, a first terminal of the first resistor R1 connected between the second and third diodes, a second terminal of the first resistor R1 connected to ground through the second resistor R2 and the third resistor R3 which are connected in series.

7. The voltage testing device of claim 6, wherein resistances of the first to third resistors R1-R3 can be calculated according to a formula of
$$\sqrt{2} * \frac{R 2 + R 3}{R 1 + R 2 + R 3} = 1.$$

8. The voltage testing device of claim 6, further comprising a first test terminal and a second test terminal, wherein the first test terminal is connected between the first resistor R1 and the second resistor R2, and the second test terminal is connected to ground.

9. The voltage testing device of claim 8, wherein the oscillograph comprises a testing probe and a grounding probe, the testing probe and the grounding probe are respectively connected to the first and second test terminals.

10. The voltage testing device of claim 8, further comprising a housing, wherein the port, the first and second test terminals are mounted on the surface of the housing; the testing circuit is mounted in the inner of the housing.

11. A voltage testing device, comprising:
a port connected to an alternating current (AC) power supply, and configured for receiving an AC voltage from the AC power supply;
a testing circuit connected to the port, and configured for filtering and rectifying the AC voltage into a direct current (DC) voltage;
a first test terminal connected to an output of the testing circuit;
a second test terminal connected to ground; and
an oscillograph comprising a testing probe and a grounding probe; wherein the testing probe and the grounding probe are respectively connected to the first and second testing terminals, the oscilloscope tests and displays the DC voltage.

12. The voltage testing device of claim 11, wherein the testing circuit comprises a filtering unit that receives and filters the AC voltage.

13. The voltage testing device of claim 12, wherein the testing circuit comprises a rectifier unit connected to the filtering unit, and the rectifier unit receives the filtered AC voltage and rectifies the filtered AC voltage into a first DC voltage.

14. The voltage testing device of claim 13, wherein the testing circuit comprises a voltage dividing unit, the testing circuit receives the first DC voltage and divides the first DC voltage into a second DC voltage, and outputs the second DC voltage to the oscillograph through the first and the second test terminals.

15. The voltage testing device of claim 14, wherein the second DC voltage equals to an effective value of the AC voltage.
